(19) United States
(12) Patent Application Publication
(10) Pub. No.: US 2026/0013305 A1
(43) Pub. Date: Jan. 8, 2026

(54) DISPLAY DEVICE, METHOD OF FABRICATING THE SAME, AND ELECTRONIC DEVICE

(71) Applicant: Samsung Display Co., Ltd., Yongin-si (KR)

(72) Inventors: Kyung Mok LEE, Yongin-si (KR); Bo Youl SHIM, Yongin-si (KR); Dong Youb LEE, Yongin-si (KR)

(21) Appl. No.: 19/251,025

(22) Filed: Jun. 26, 2025

(30) Foreign Application Priority Data
Jul. 8, 2024 (KR) 10-2024-0089521

(51) Int. Cl. H10H 29/854; G06F 1/16; H01L 25/16; H10H 29/01; H10H 29/45; H10H 29/49

(52) U.S. Cl. CPC H10H 29/854; G06F 1/1618; H01L 25/167; H10H 29/012; H10H 29/0362; H10H 29/0364; H10H 29/45; H10H 29/49

(57) ABSTRACT

A display device includes: a display panel including a first area, a second area formed to be bendable from the first area, and a third area extending from the second area; a driving chip in the third area; a connection substrate including a first hole overlapping the driving chip and a second hole overlapping the third area, and overlapping at least a portion of the third area; and a first resin layer in the second hole.

### CROSS-REFERENCE TO RELATED APPLICATION

The present application claims priority to and the benefit of Korean Patent Application No. 10-2024-0089521, filed on Jul. 8, 2024, in the Korean Intellectual Property Office, the entire disclosure of which is incorporated herein by reference.

### BACKGROUND

### 1. Field

Aspects of some embodiments of the present disclosure relate to a display device, a method of fabricating the display device, and an electronic device.

### 2. Description of Related Art

With the development of information technology, the importance of display devices as a mechanism to connect users and information has been emphasized. Hence, research and development on display devices has been continuously performed.

Display devices may include a display panel in which light emitting elements are arranged, and a connection substrate (e.g., a flexible printed circuit board) that can electrically connect the display panel to a driving circuit provided to drive the display panel.

The above information disclosed in this Background section is only for enhancement of understanding of the background and therefore the information discussed in this Background section does not necessarily constitute prior art.

### SUMMARY

Aspects of some embodiments of the present disclosure include to a display device, an electronic device including the display device and a method of fabricating the display device, which may relatively improve adhesive force between a display panel and a connection substrate, thereby relatively reducing the defect rate.

According to some embodiments of the present disclosure, a display device includes: a display panel including a first area, a second area formed to be bendable from the first area, and a third area extending from the second area; a driving chip in the third area; a connection substrate including a first hole overlapping the driving chip and a second hole overlapping the third area, and overlapping at least a portion of the third area; and a first resin layer in the second hole.

According to some embodiments, the second hole may pass through the connection substrate.

According to some embodiments, the first resin layer may contact at least a portion of the display panel.

According to some embodiments, the second hole may have a shape of any one of a circle, an ellipse, and a polygon.

According to some embodiments, the second hole may have a circular shape. A diameter of the second hole may range from 30 μm to 1 mm.

According to some embodiments, the second hole may have an elliptical shape. According to some embodiments, a semi-minor axis of the second hole may range from 30 μm to 1 mm.

According to some embodiments, the second hole may have a polygonal shape. According to some embodiments, a shortest diagonal length of the second hole may range from 30 μm to 1 mm.

According to some embodiments, the first resin layer may include at least one of a thermosetting material or a photo-curable material.

According to some embodiments, the connection substrate may further include a third hole overlapping the third area. According to some embodiments, the display device may further include a second resin layer in the third hole.

According to some embodiments, the third hole may pass through the connection substrate, and may not overlap the second hole in a plan view.

According to some embodiments, each of the second hole and the third hole may have a shape of any one of a circle, an ellipse, and a polygon.

According to some embodiments, each of the first resin layer and the second resin layer may include at least one of a thermosetting material or a photo-curable material.

According to some embodiments of the present disclosure, a display device includes: a display panel including a first area, a second area formed to be bendable from the first area, and a third area extending from the second area; a driving chip in the third area; a connection substrate including a first hole overlapping the driving chip; and a cover film on the connection substrate. According to some embodiments, the connection substrate may include: a first substrate area positioned on a first side of the connection substrate; a second substrate area positioned on a second side of the connection substrate; and a third substrate area positioned between the first substrate area and the second substrate area. According to some embodiments, a length of the connection substrate in a first direction in the third substrate area may differ from a length of the connection substrate in the first direction in each of the second substrate area and the first substrate area. According to some embodiments, the cover film may contact at least a portion of the display panel.

According to some embodiments, each of the first substrate area and the second substrate area may protrude further in a direction opposite to the first direction than the third substrate area. According to some embodiments, the first direction may correspond to a direction in which the first area and the third area are spaced apart from each other.

According to some embodiments, the third substrate area may protrude further in a direction opposite to the first direction than each of the first substrate area and the second substrate area.

According to some embodiments of the present disclosure, a method of fabricating a display device includes: forming a display panel including a first area, a second area formed to be bendable from the first area, and a third area extending from the second area; forming a driving chip in the third area; forming a connection substrate including a first hole and a second hole; attaching the connection substrate on the display panel; forming a base resin layer in the second hole; and curing the base resin layer. According to some embodiments, the first hole may be formed to overlap the driving chip. According to some embodiments, the second hole may be formed to overlap the third area.

According to some embodiments, forming the connection substrate may include forming the second hole such that the second hole passes through the connection substrate.

According to some embodiments, forming the base resin layer may include applying resin into the second hole. According to some embodiments, the resin may include at least one of a thermosetting material or a photo-curable material.

According to some embodiments, curing the base resin layer may include at least one of photo-curing the base resin layer or thermally curing the base resin layer.

According to some embodiments, forming the connection substrate may include forming the second hole to have a shape of any one of a circle, an ellipse, and a polygon.

According to some embodiments of the present disclosure, an electronic device includes: a display device and a processor. And the display device includes: a display panel including a first area, a second area formed to be bendable from the first area, and a third area extending from the second area; a driving chip in the third area; a connection substrate including a first hole overlapping the driving chip.

According to some embodiments, the connection substrate further includes a second hole overlapping the third area, and overlapping at least a portion of the third area. According to some embodiments, the display device further includes a first resin layer in the second hole.

According to some embodiments, the display device further includes a cover film on the connection substrate. According to some embodiments, the connection substrate may include: a first substrate area positioned on a first side of the connection substrate; a second substrate area positioned on a second side of the connection substrate; and a third substrate area positioned between the first substrate area and the second substrate area. According to some embodiments, a length of the connection substrate in a first direction in the third substrate area may differ from a length of the connection substrate in the first direction in each of the second substrate area and the first substrate area. According to some embodiments, the cover film may contact at least a portion of the display panel.

### BRIEF DESCRIPTION OF THE DRAWINGS

FIG. 1 is a schematic perspective view of a display device according to some embodiments.

FIG. 2 is a schematic perspective view of the display device folded on a folding axis according to some embodiments.

FIG. 3 is a schematic perspective view of the display device folded on the folding axis according to some embodiments.

FIG. 4 is a schematic plan view of the display panel according to some embodiments.

FIG. 5 is a schematic sectional view of the display device according to some embodiments.

FIGS. 6 and 7 are schematic plan views of a display device according to some embodiments.

FIGS. 8 and 9 are schematic plan views of a display device according to some embodiments.

FIG. 10 is a schematic flowchart showing a method of fabricating a display device according to some embodiments.

FIGS. 11 to 13 are schematic diagrams for describing the method of fabricating the display device according to some embodiments.

FIG. 14 is a block diagram of an electronic device according to some embodiments.

FIG. 15 shows schematic views of various embodiments of an electronic device.

### DETAILED DESCRIPTION

As the present disclosure allows for various changes and numerous embodiments, particular embodiments will be illustrated in the drawings and described in detail in the written description. However, this is not intended to limit the present disclosure to particular modes of practice, and it is to be appreciated that all changes, equivalents, and substitutes that do not depart from the spirit and technical scope of the present disclosure are encompassed in the present disclosure.

It will be understood that, although the terms “first”, “second”, etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element. In the present disclosure, the singular forms are intended to include the plural forms as well, unless the context clearly indicates otherwise.

It will be further understood that the terms “comprise”, “include”, “have”, etc. when used in the present disclosure, specify the presence of stated features, integers, steps, operations, elements, components, and/or combinations of them but do not preclude the presence or addition of one or more other features, integers, steps, operations, elements, components, and/or combinations thereof. Furthermore, in case that a first part such as a layer, a film, a region, or a plate is located on a second part, the first part may be not only directly on the second part but a third part may intervene between them. In addition, when it is expressed that a first part such as a layer, a film, a region, or a plate is formed on a second part, the surface of the second part on which the first part is formed is not limited to an upper surface of the second part but may include other surfaces such as a side surface or a lower surface of the second part. To the contrary, in case that a first part such as a layer, a film, a region, or a plate is under a second part, the first part may be not only directly under the second part but a third part may intervene between them.

Aspects of some embodiments of the present disclosure relate to a display device and a method of fabricating the display device. Hereinafter, a display device and a method of fabricating the display device according to some embodiments will be described with reference to the attached drawings.

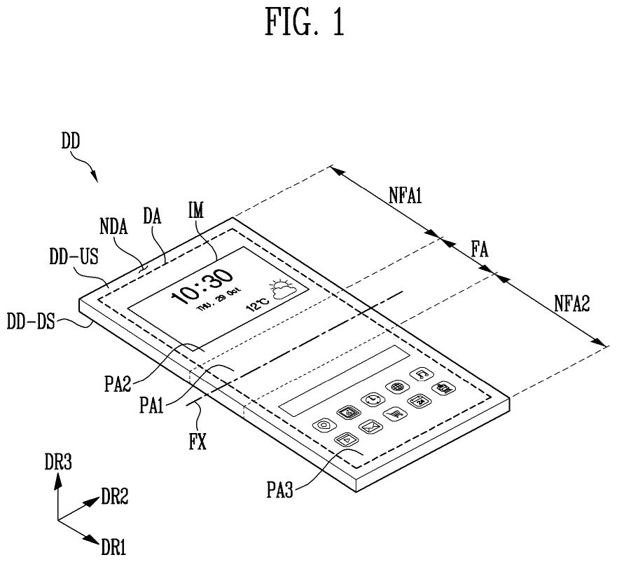

FIG. 1 is a schematic perspective view of a display device DD according to some embodiments.

Referring to FIG. 1, the display device DD may include a plurality of areas divided from each other on a display surface. The display surface may be divided into a display area DA and a non-display area NDA based on whether an image IM is displayed. The display area DA may be an area in which the image IM is displayed, and the non-display area NDA may be an area in which the image IM is not displayed. For example, the display device DD illustrated in FIG. 1 may be provided as a smartphone with a rectangular shape. The display device DD may display images IM such as a weather information image and icon images. The non-display area NDA may be adjacent to (e.g., in a periphery or outside a footprint of) the display area DA or enclose the display area DA, and may be omitted according to some embodiments of the present disclosure.

The display surface may be parallel to a surface defined in a first direction DR1 and a second direction DR2. A normal direction of the display surface may indicate a third direction DR3. The third direction DR3 may indicate a thickness direction of the display panel DD. A front surface and a rear surface of each component may be distinguished from each other in the third direction DR3.

Here, the directions indicated by the first to third directions DR1, DR2 and DR3 are relative concepts, and may be switched to other directions. Hereinafter, the first to third directions DR1, DR2, and DR3 refer to the same reference numerals in the directions indicated by the first to third direction axes DR1, DR2, and DR3, respectively. Furthermore, in the present specification, a surface defined by the first direction DR1 and the second direction DR2 may be defined as a plane, and the phrases “viewed in a plane” or “in a plan view” refers to being viewed in the third direction DR3 (e.g., from a direction normal or perpendicular to a plane defined by the first direction DR1 and the second direction DR2).

The display device DD may include a folding area FA formed to be foldable on a folding axis FX, and a first non-folding area NFA1 and a second non-folding area NFA2 that are spaced apart from each other with the folding area FA interposed therebetween. The folding axis FX may extend in the second direction DR2. The first non-folding area NFA1 may extend from one end of the folding area FA in the first direction DR1. The second non-folding area NFA2 may extend from the other end of the folding area FA in the first direction DR1.

An upper surface DD-US of the display device DD may include a first display surface PA1 overlapping the folding area FA, a second display surface PA2 overlapping the first non-folding area NFA1, and a third display surface PA3 overlapping the second non-folding area NFA2. A lower surface DD-DS of the display device DD may be a surface facing away from the upper surface DD-US. Each of the first to third display surfaces PA1, PA2, and PA3 may display an image.

According to some embodiments of the present disclosure, the display device DD is illustratively shown as a foldable display device, but embodiments according to the present disclosure are not limited thereto, and may be applied to various display devices such as a flexible display device, a curved display device, a rollable display device, and a stretchable display device. Furthermore, the foldable display device in accordance with the present disclosure may be used not only in large electronic devices such as televisions or outdoor billboards, but also in small to medium-sized electronic devices such as mobile phones, personal computers, laptop computers, personal digital terminals, vehicle navigation units, gaming consoles, portable electronic devices, wristwatch-type electronic devices, and cameras.

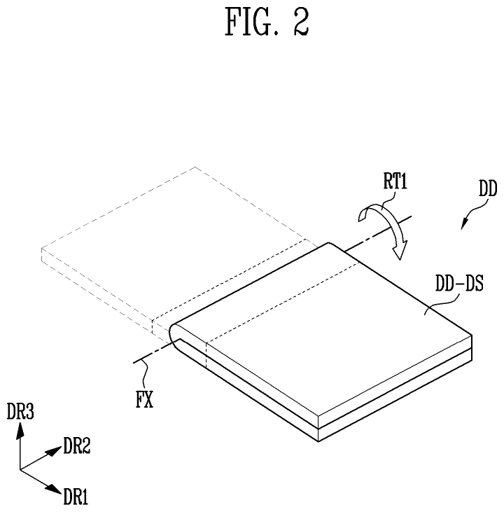

FIG. 2 is a schematic perspective view of a display device DD folded on a folding axis FX according to some embodiments.

Referring to FIGS. 1 and 2, the folding area FA may be folded on the folding axis FX so that the second display surface PA2 and the third display surface PA3 can face each other. The folding area FA may be folded in a first rotational direction RT1. The lower surface DD-DS of the display device DD may be exposed to the outside.

In this way, the display device DD may be folded along the folding axis FX, which may be defined as inner folding.

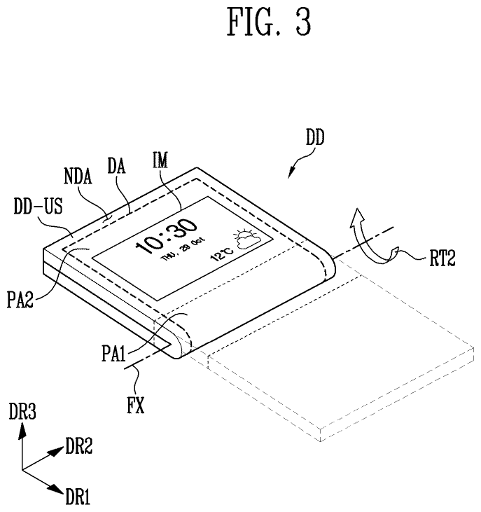

FIG. 3 is a schematic perspective view of a display device DD folded along a folding axis DX according to some embodiments.

Referring to FIGS. 1 and 3, the folding area FA may be folded on the folding axis FX so that the second display surface PA2 and the third display surface PA3 can be exposed to the outside. The folding area FA may be folded in a second rotational direction RT2. The upper surface DD-US of the display device DD may be exposed to the outside.

The display device DD may be folded on the folding axis FX so that the second display surface PA2 of the first non-folding area NFA1 and the third display surface PA3 of the second non-folding area NFA2 faces the outside, which is defined as outer folding.

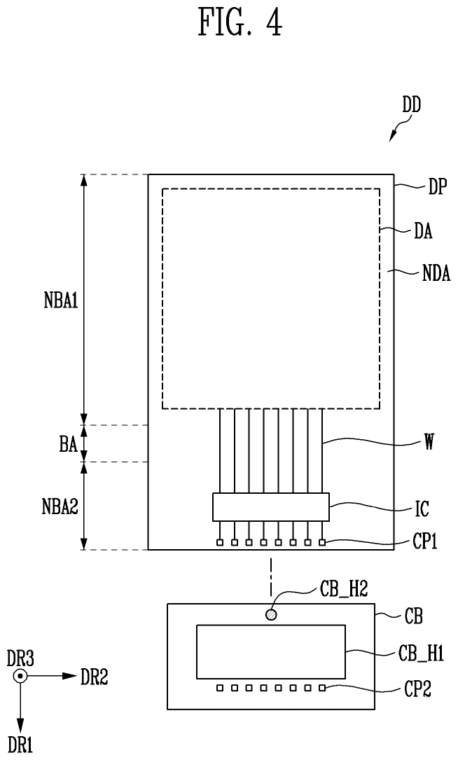

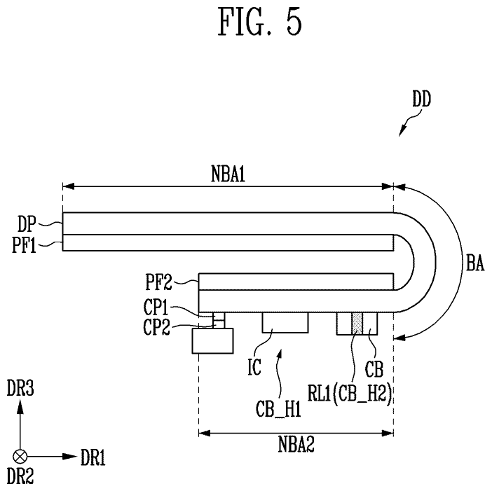

Hereinafter, a display device DD according to some embodiments will be described with reference to FIGS. 4 and 5. The display device DD illustrated in FIGS. 4 and 5 may be a display device DD according to some embodiments. FIG. 4 is a schematic plan view of the display panel DD according to some embodiments. FIG. 5 is a schematic sectional view of the display device DD according to some embodiments. For the sake of convenience in explanation, FIG. 4 illustratively shows a plan view in which a connection substrate CB is not coupled to the display panel DP. FIG. 5 illustratively shows a sectional view in which the display panel DP is bent.

Referring to FIGS. 4 and 5, the display device DD may include a display panel DP, a driving chip IC, a first connection pad CP1, a connection substrate CB, and a first resin layer RL1.

The display panel DP according to some embodiments of the present disclosure may be an emission type display panel. For example, the display panel DP may be an organic light emitting display panel, a quantum dot light emitting display panel, a micro-LED display panel, or a nano-LED display panel.

Pixels and a plurality of lines W connected to the pixels may be located in the display area DA. The lines W may include a data line, a power line, a control signal line, a scan line, an emission control line, and the like.

A driving circuit configured to provide various signals to the pixels may be located in the non-display area NDA. The driving circuit may include a scan driving circuit, an emission control driving circuit, and the like.

The display panel DP may include a first area NBA1, a second area BA, and a third area NBA2. The first area NBA1 and the third area NBA2 may be spaced apart from each other in the first direction DR1 with the second area BA interposed therebetween.

The first area NBA1 may be an area provided to display images, and may be the area including the folding area FA, the first non-folding area NFA1, and the second non-folding area NFA2 that are described with reference to FIG. 1.

The second area BA may be bent in one direction. For example, the second area BA may be bent in a direction opposite to the upper surface of the display panel DP, that is, in a direction opposite to the third direction DR3.

The driving chip IC may be a chip in which circuits for driving the display panel DP are integrated. The driving chip IC may output image signals and driving signals needed to display an image. The driving chip IC may be located in the third area NBA2 using a method such as a chip-on-plastic (COP) or chip-on-glass (COG) method. The driving chip IC may be connected to the first connection pad CP1 through the lines W.

The first connection pad CP1 may be electrically connected to a second connection pad CP2 of the connection substrate CB. Accordingly, the first connection pad CP1 may receive various signals for driving the display panel DP through the connection substrate CB. Furthermore, the first connection pad CP1 may be connected to the lines W extending from the display area DA.

The connection substrate CB may include a first hole CB_H1, a second hole CB_H2, and the second connection pad CP2.

Referring to FIG. 5, the connection substrate CB may be arranged to overlap at least a portion of the third area NBA2. The connection substrate CB may be electrically connected to the driving chip IC through the second connection pad CP2. The connection substrate CB may be a flexible printed circuit board (FPCB).

The first hole CB_H1 may be formed to overlap the driving chip IC. For example, the first hole CB_H1 may overlap the driving chip IC in a plan view. Accordingly, physical interference (or contact) between the driving chip IC and the connection substrate CB may be prevented or reduced.

The second hole CB_H2 may be formed to overlap the third area NBA2 of the display panel DP. For example, the second hole CB_H2 may overlap the third area NBA2 of the display panel DP in a plan view. The second hole CB_H2 may be formed so as not to overlap the first hole CB_H1. For example, the second hole CB_H2 may not overlap the first hole CB_H1 in a plan view.

The second hole CB_H2 may be formed on one side of the first hole CB_H1. For example, the second hole CB_H2 may be formed on an upper side of the first hole CB_H1. Embodiments according to the present disclosure are not limited to the aforementioned example, and the second hole CB_H2 may be an area overlapping the third area NBA2 of the display panel DP, and may be formed on any one of right, left, and lower sides of the first hole CB_H1.

The second hole CB_H2 may have a shape of one of a circle, an ellipse, and a polygon in a plan view. In the case where the second hole CB_H2 has a circular shape, a diameter of the second hole CB_H2 may range from 30 μm to 1 mm. In the case where the diameter of the second hole CB_H2 is less than 30 μm, the first resin layer RL1 may not be properly formed in the second hole CB_H2. In the case where the second hole CB_H2 has an elliptical shape, a semi-minor axis of the second hole CB_H2 may range from 30 micrometers (μm) to 1 millimeter (mm). In the case where the second hole CB_H2 has a polygonal shape, a shortest diagonal length of the second hole CB_H2 may range from 30 μm to 1 mm.

The first resin layer RL1 may be located in the second hole CB_H2. The first resin layer RL1 may be located in the second hole CB_H2, and may contact at least a portion of the display panel DP.

The first resin layer RL1 may include a curable material. For example, the first resin layer RL1 may include at least one of a thermosetting material or a photo-curable material. For example, the first resin layer RL1 may include ultraviolet curable resin as the photo-curable material. For instance, the first resin layer RL1 may include, as the photo-curable material, at least one of epoxy acrylate resin, polyester acrylate resin, urethane acrylate resin, polyether acrylate resin, silicon acrylate resin, or alkyl acrylate resin. For example, the first resin layer RL1 may include at least one of epoxy resin, phenol resin, urea resin, melamine resin, or polyurethane resin, as the thermosetting material. However, embodiments according to the present disclosure are not limited to the aforementioned example, and the first resin layer RL1 may include various curable materials.

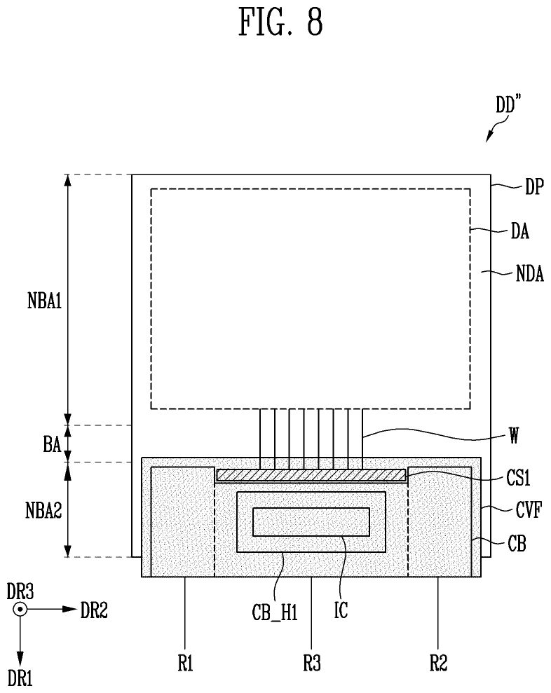

The first resin layer RL1 may be located in the second hole CB_H2, thereby increasing adhesive force between the display panel DP and the connection substrate CB. Due to an increase in the adhesive force between the display panel DP and the connection substrate CB, the display device DD according to some embodiments may not further include a cover film CVF (refer to FIG. 8) located on the connection substrate CB. The cover film CVF may be located on the connection substrate CB, and may contact at least a portion of the display panel DP, thereby fixing the connection substrate CB to the display panel DP. However, in the case where a surface area of the non-display area NDA (e.g., dead space) is reduced, a surface area of an area where the cover film CVF can contact the display panel DP may be relatively reduced, and there may be a risk that the cover film CVF may not reliably fix the connection substrate CB to the display panel DP. In the case where the connection substrate CB is not reliably fixed to the display panel DP, the defect rate of the display device DD may increase.

The display device DD according to some embodiments of the present disclosure may include the first resin layer RL1, which increases the adhesive force between the display panel DP and the connection substrate CB. As a result, the connection substrate CB may be fixed to the display panel DP even without the need for the cover film CVF in the display device DD, thereby relatively reducing the defect rate of the display device DD.

The second connection pad CP2 may be electrically connected to the first connection pad CP1. To this end, the second connection pad CP2 may be formed at a position corresponding to the first connection pad CP1. The second connection pad CP2 may be connected to the first connection pad CP1 by a film-on-glass (FOG) method.

The display device DD may further include a first protective film PF1 and a second protective film PF2.

The first protective film PF1 may be located on the rear surface of the display panel DP. The first protective film PF1 may be located on a portion corresponding to the first area NBA1. In other words, the first protective film PF1 may be located on the rear surface of the first area NBA1. The first protective film PF1 may support a portion of the first area NBA1 so as not to be bent when the display panel DP is bent. The first protective film PF1 may include a polyethylene terephthalate (PET) film or the like. However, embodiments according to the present disclosure are not limited to the aforementioned example.

The second protective film PF2 may be located on the rear surface of the display panel DP. The second protective film PF2 may be located on a portion corresponding to the third area NBA2. In other words, the second protective film PF2 may be located on the rear surface of the third area NBA2. The second protective film PF2 may support a portion of the third area NBA2 so as not to be bent when the display panel DP is bent. The second protective film PF2 may include a PET film or the like. However, embodiments according to the present disclosure are not limited to the aforementioned example.

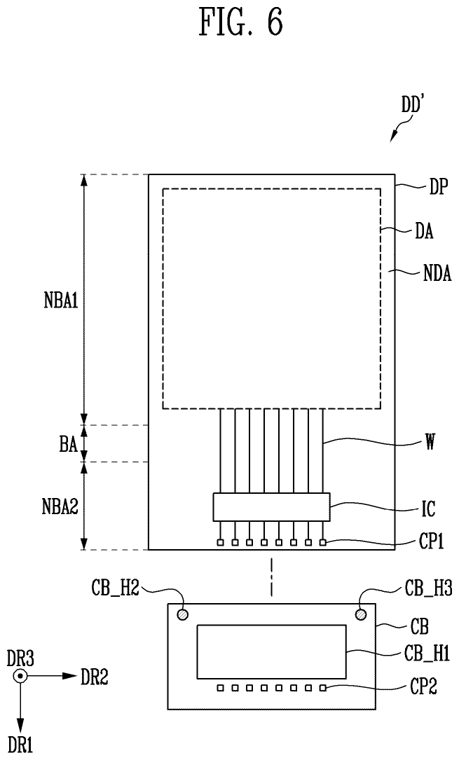

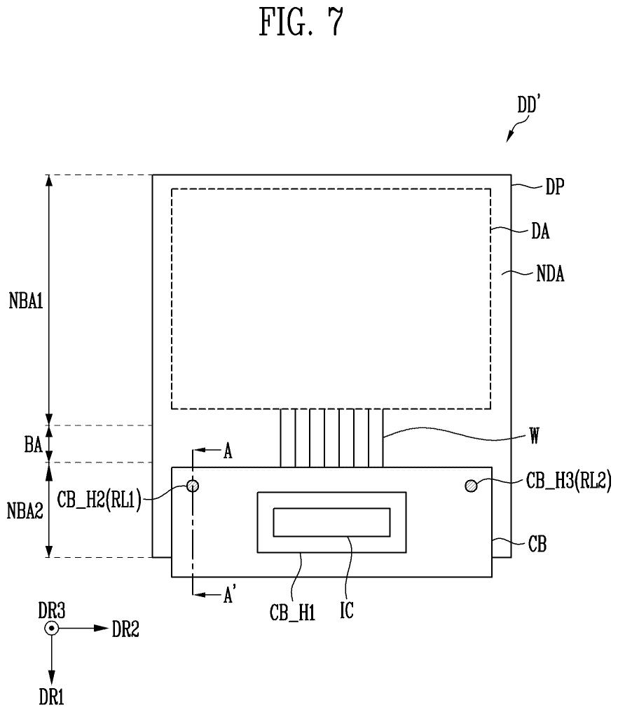

Hereinafter, a display device DD′ according to some embodiments will be described in more detail with reference to FIGS. 6 and 7. The display device DD′ illustrated in FIGS. 6 and 7 may be a display device DD according to some embodiments. FIGS. 6 and 7 are schematic plan views of the display device DD′ according to some embodiments. FIG. 6 illustrates a plan view in which the connection substrate CB is not coupled to the display panel DP. FIG. 7 illustrates a plan view in which the connection substrate CB is coupled to the display panel DP.

The display device DD′ in accordance with second embodiments is different from the first embodiments in which the display device DD′ further includes a third hole CB_H3 and a second resin layer RL2. Hereinafter, descriptions of contents overlapping the above-described contents will be omitted.

The connection substrate CB may further include the third hole CB_H3. The third hole CB_H3 may be formed to overlap the third area NBA2 of the display panel DP. For example, the third hole CB_H3 may overlap the third area NBA2 of the display panel DP in a plan view.

The third hole CB_H3 may be formed so as not to overlap the second hole CB_H2. For example, the third hole CB_H3 may not overlap the second hole CB_H2 in a plan view. The first hole CB_H1, the second hole CB_H2, and the third hole CB_H3 may not overlap each other in a plan view.

The third hole CB_H3 may be formed on one side of the first hole CB_H1. For example, the third hole CB_H3 may be formed on an upper side of the first hole CB_H1. Embodiments according to the present disclosure are not limited to the aforementioned example, and the third hole CB_H3 may be an area overlapping the third area NBA2 of the display panel DP, and may be formed on any one of right, left, and lower sides of the first hole CB_H1.

The third hole CB_H3 may have a shape of one of a circle, an ellipse, and a polygon in a plan view. In the case where the third hole CB_H3 has a circular shape, a diameter of the third hole CB_H3 may range from 30 μm to 1 mm. In the case where the diameter of the third hole CB_H3 is less than 30 μm, the second resin layer RL2 may not be properly formed in the third hole CB_H3. In the case where the third hole CB_H3 has an elliptical shape, a semi-minor axis of the third hole CB_H3 may range from 30 μm to 1 mm. In the case where the third hole CB_H3 has a polygonal shape, a shortest diagonal length of the third hole CB_H3 may range from 30 μm to 1 mm.

The second resin layer RL2 may be located in the third hole CB_H3. The second resin layer RL2 may be located in the third hole CB_H3, and may contact at least a portion of the display panel DP. For example, the second resin layer RL2 may include at least one of a thermosetting material or a photo-curable material. For example, the second resin layer RL2 may include ultraviolet curable resin as the photo-curable material. For instance, the second resin layer RL2 may include, as the photo-curable material, at least one of epoxy acrylate resin, polyester acrylate resin, urethane acrylate resin, polyether acrylate resin, silicon acrylate resin, or alkyl acrylate resin. For example, the second resin layer RL2 may include at least one of epoxy resin, phenol resin, urea resin, melamine resin, or polyurethane resin, as the thermosetting material. However, embodiments according to the present disclosure are not limited to the aforementioned example, and the second resin layer RL2 may include various curable materials.

The second resin layer RL2 may be located in the third hole CB_H3, thereby increasing adhesive force between the display panel DP and the connection substrate CB. As described above, the display device DD according to some embodiments may further include the second resin layer RL2, thereby increasing the adhesive force between the display panel DP and the connection substrate CB. As a result, the connection substrate CB may be more reliably fixed to the display panel DP.

According to some embodiments, the connection substrate CB may include not only the first hole CB_H1, the second hole CB_H2, and the third hole CB_H3 but also additional holes. For example, the connection substrate CB may further include a fourth hole formed to overlap the third area NBA2 of the display panel DP. The number of holes formed to overlap the third area NBA2 is not limited to an example illustrated in the drawings.

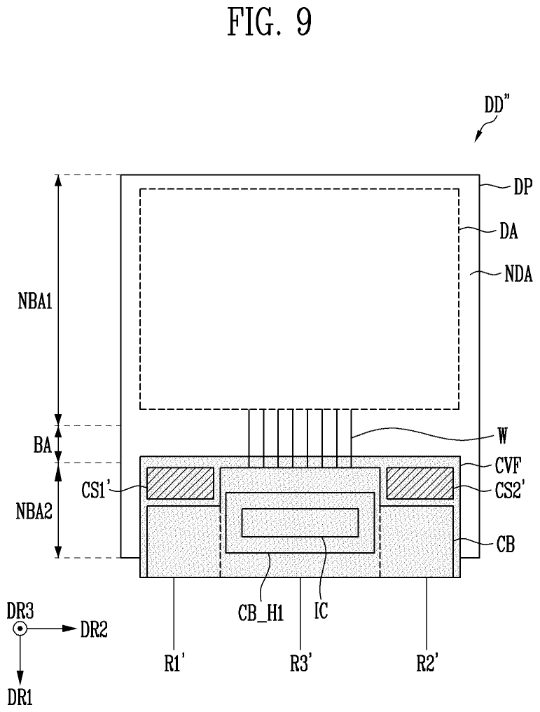

Hereinafter, a display device DD″ according to some embodiments will be described with reference to FIGS. 8 and 9. The display device DD″ illustrated in FIGS. 8 and 9 may be a display device DD according to some embodiments. FIGS. 8 and 9 are schematic plan views of the display device DD″ according to some embodiments.

The display device DD″ in accordance with the third embodiments is different from the foregoing embodiments in that the display device DD″ does not include the second hole CB_H2 and the third hole CB_H3. Hereinafter, descriptions of contents overlapping the above-described contents will be omitted.

Referring to FIG. 8, the connection substrate CB may include a first substrate area R1, a second substrate area R2, and a third substrate area R3. The first substrate area R1 may be positioned on one side (e.g., a left side) of the connection substrate CB. The second substrate area R2 may be positioned on the other side (e.g., a right side) of the connection substrate CB. The first substrate area R1 and the second substrate area R2 may be spaced apart from each other in the second direction DR2. The third substrate area R3 may be positioned between the first substrate area R1 and the second substrate area R2. The third substrate area R3 may be in contact with the first substrate area R1 and the second substrate area R2.

A length of the first substrate area R1 in the first direction DR1 may differ from a length of the third substrate area R3 in the first direction DR1. For example, the length of the first substrate area R1 in the first direction DR1 may be greater than the length of the third substrate area R3 in the first direction DR1. For example, the first substrate area R1 may protrude further in a direction opposite to the first direction DR1 compared to the third substrate area R3. The first direction DR1 may be a direction in which the lines W extend. The first direction DR1 may be a direction in which the first area NBA1 and the third area NBA2 are spaced apart from each other.

A length of the second substrate area R2 in the first direction DR1 may differ from the length of the third substrate area R3 in the first direction DR1. The length of the second substrate area R2 in the first direction DR1 may be greater than the length of the third substrate area R3 in the first direction DR1. For example, the second substrate area R2 may protrude further in the direction opposite to the first direction DR1 compared to the third substrate area R3.

The first substrate area R1, the second substrate area R2, and the third substrate area R3 may define a first attaching area CS1. For example, the first attaching area CS1 may be defined by the third substrate area R3 and respective portions of the first substrate area R1 and the second substrate area R2 that protrude further in the direction opposite to the first direction DR1 compared to the third substrate area R3. For example, the first attaching area CS1 may be located between the first substrate area R1 and the second substrate area R2 that protrude further in the direction opposite to the first direction DR1 compared to the third substrate area R3.

The display device DD″ may include a cover film CVF. The cover film CVF may be located on the connection substrate CB. The cover film CVF may contact at least a portion of the connection substrate CB and at least a portion of the display panel DP. For example, the cover film CVF may cover at least a portion of the connection substrate CB and contact the first attaching area CS1 of the display panel DP.

Because the first attaching area CS1 is formed, the cover film CVF may contact the first attaching area CS1, thereby increasing adhesive force between the display panel DP and the cover film CVF. Even if the surface area of the non-display area NDA (e.g., dead space) is reduced, the cover film CVF may contact the first attaching area CS1, thereby reliably fixing the connection substrate CB to the display panel DP.

Referring to FIG. 9, a length of a first substrate area R1′ in the first direction DR1 may be less than a length of a third substrate area R3′ in the first direction DR1. For example, the third substrate area R3′ may protrude further in the direction opposite to the first direction DR1 compared to the first substrate area R1′.

A length of a second substrate area R2′ in the first direction DR1 may be less than the length of the third substrate area R3′ in the first direction DR1. For example, the third substrate area R3′ may protrude further in the direction opposite to the first direction DR1 compared to the second substrate area R2′.

The first substrate area R1′ and the third substrate area R3′ may define a first attaching area CS1′. For example, the first attaching area CS1′ may be defined by the first substrate area R1′ and the third substrate area R3′ that protrudes further in the direction opposite to the first direction DR1 compared to the first substrate area R1′. For instance, the first attaching area CS1′ may be located on a left side of the third substrate area R3′ that protrudes further in the direction opposite to the first direction DR1 compared to the first substrate area R1′.

The second substrate area R2′ and the third substrate area R3′ may define a second attaching area CS2′. For example, the second attaching area CS2′ may be defined by the second substrate area R2′ and the third substrate area R3′ that protrudes further in the direction opposite to the first direction DR1 compared to the second substrate area R2′. For instance, the second attaching area CS2′ may be located on a right side of the third substrate area R3′ that protrudes further in the direction opposite to the first direction DR1 compared to the second substrate area R2′.

Because the first attaching area CS1′ and the second attaching area CS2′ are formed, the cover film CVF may contact the first attaching area CS1′ and the second attaching area CS2′, thereby increasing adhesive force between the display panel DP and the cover film CVF. Even if the surface area of the non-display area NDA (e.g., dead space) is reduced, the cover film CVF may contact the first attaching area CS1′ and the second attaching area CS2′, and the cover film CVF may reliably fix the connection substrate CB to the display panel DP.

The numbers of first attaching areas CS1′ and second attaching areas CS2′ are not limited to examples illustrated in the drawings. The positions of the first attaching area CS1′ and the second attaching area CS2′ are also not limited to examples illustrated in the drawings.

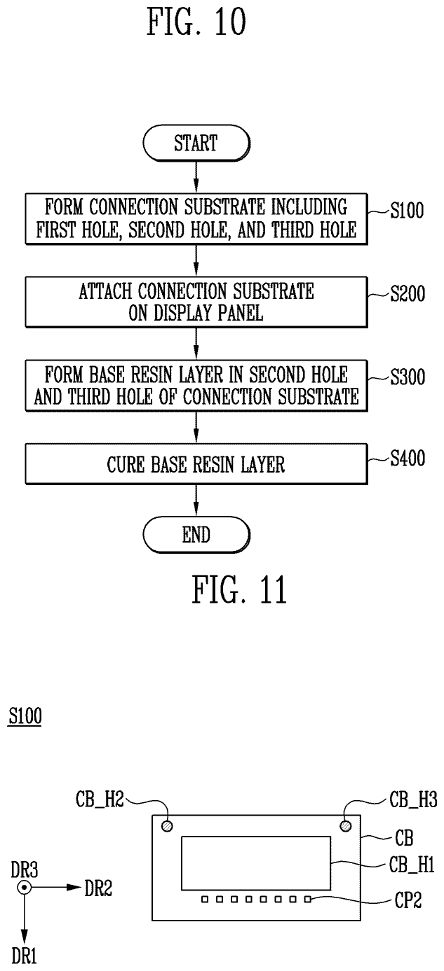

Hereinafter, a method of fabricating the display device DD according to some embodiments will be described with reference to FIGS. 10 to 13. FIG. 10 is a schematic flowchart showing a method of fabricating the display device DD according to some embodiments. FIGS. 11 to 13 are schematic diagrams for describing the method of fabricating the display device DD according to some embodiments.

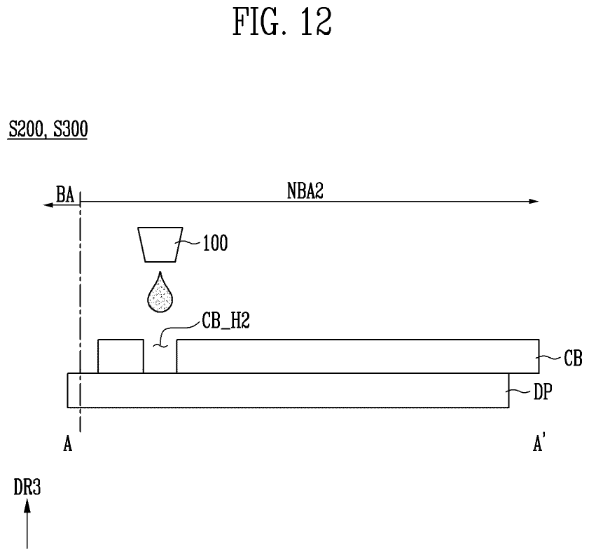

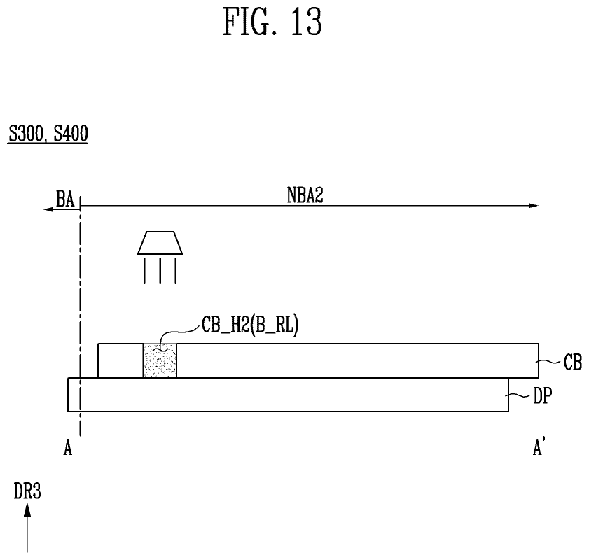

The method of fabricating the display device DD illustrated in FIGS. 10 to 13 refers to a method of fabricating the display device DD including the second hole CB_H2 and the third hole CB_H3. FIGS. 12 and 13 are sectional views showing the method of fabricating the display device DD taken along line A-A′ of FIG. 7. Hereinafter, for the sake of convenience in explanation, the method of fabricating the display device DD will be described, based on the display device DD including the second hole CB_H2 and the third hole CB_H3.

Referring to FIG. 10, the method of fabricating the display device DD may include operation S100 of forming a connection substrate including a first hole, a second hole, and a third hole, operation S200 of attaching the connection substrate on the display panel, operation S300 of forming the base resin layer in the second hole and the third hole of the connection substrate, and operation S400 of curing the base resin layer.

The display panel DP may be prepared before operation S200 of attaching the connection substrate on the display panel. The method of fabricating the display device DD may further include the operation of forming the display panel DP including the first area NBA1, the second area BA, and the third area NBA2. The driving chip IC may be formed on the display panel DP. The method of fabricating the display device DD may further include the operation of forming the driving chip IC in the third area NBA2.

Referring to FIG. 11 together with FIG. 7, operation S100 of forming the connection substrate including the first hole CB_H1, the second hole CB_H2, and the third hole CB_H3 may include the operation of forming the first hole CB_H1 to overlap the driving chip IC, and the operation of forming the second hole cB_H2 and the third hole CB_H3 to overlap the third area NBA2 of the display panel DP. According to some embodiments, in the case where the display device DD does not include the third hole CB_H3, the operation of forming the third hole CB_H3 to overlap the third area NBA2 of the display panel DP may be omitted.

Each of the first hole CB_H1, the second hole CB_H2, and the third hole CB_H3 may be formed to pass through the connection substrate CB. For example, when the connection substrate CB is located on the display panel DP, each of the first hole CB_H1, the second hole CB_H2, and the third hole CB_H3 may expose the display panel DP.

The first hole CB_H1, the second hole CB_H2, and the third hole CB_H3 may be formed so as not to overlap each other. For example, each of the first hole CB_H1, the second hole CB_H2, and the third hole CB_H3 may not overlap each other in a plan view.

Each of the second hole CB_H2 and the third hole CB_H3 may have a shape of one of a circle, an ellipse, and a polygon in a plan view. In the case where each of the second hole CB_H2 and the third hole CB_H3 has a circular shape, a diameter of each of the second hole CB_H2 and the third hole CB_H3 may range from 30 μm to 1 mm. In the case where each of the second hole CB_H2 and the third hole CB_H3 has an elliptical shape, a semi-minor axis of each of the second hole CB_H2 and the third hole CB_H3 may range from 30 μm to 1 mm. In the case where each of the second hole CB_H2 and the third hole CB_H3 has a polygonal shape, a shortest diagonal length of each of the second hole CB_H2 and the third hole CB_H3 may range from 30 μm to 1 mm.

Referring to FIGS. 12 and 13 together with FIG. 7, operation S200 of attaching the connection substrate on the display panel may include the operation of arranging the connection substrate CB on the display panel DP. The connection substrate CB may be attached on the display panel DP.

Operation S300 of forming the base resin layer in the second hole and the third hole of the connection substrate may include an operation of applying resin into each of the second hole CB_H2 and the third hole CB_H3 using a dispenser 100. The resin may be applied to the inside of each of the second hole CB_H2 and the third hole CB_H3, thereby forming a base resin layer B_RL. Each of the second hole CB_H2 and the third hole CB_H3 may be filled with the resin (or the base resin layer B_RL). The resin (or the base resin layer B_RL) may include at least one of a thermosetting material or a photo-curable material. However, embodiments according to the present disclosure are not limited to the aforementioned example.

The process of applying the resin using the dispenser 100 may employ at least one of a jet dispenser method, an inkjet method, or a one drop filling (ODF) method.

A height of the base resin layer B_RL may be less than or equal to a height of the connection substrate CB. In the present disclosure, the height of each component may be defined in the third direction DR3.

Operation S400 of curing the base resin layer may include curing the base resin layer B_RL formed in each of the second hole CB_H2 and the third hole CB_H3. Operation S400 of curing the base resin layer may include at least one of the operation of photo-curing the base resin layer B_RL, or the operation of thermally-curing the base resin layer B_RL.

In the case where the base resin layer B_RL includes photo-curable material, operation S400 of curing the base resin layer may include the operation of photo-curing the base resin layer B_RL. The operation of photo-curing the base resin layer B_RL may include the operation of irradiating the base resin layer B_RL with light. According to some embodiments, the light may include ultraviolet rays.

In the case where the base resin layer B_RL includes thermosetting material, operation S400 of curing the base resin layer may include the operation of thermally curing the base resin layer B_RL. The operation of thermally curing the base resin layer B_RL may include the operation of applying heat to the base resin layer B_RL.

The base resin layer B_RL located in the second hole CB_H2 may be cured, thus forming the first resin layer RL1. The base resin layer B_RL located in the third hole CB_H3 may be cured, thus forming the second resin layer RL2. Because the first resin layer RL1 and the second resin layer RL2 are formed, the adhesive force between the display panel DP and the connection substrate CB may increase. As a result, the connection substrate CB may be more reliably fixed to the display panel DP.

According to some embodiments, in the case where the display device DD include neither the second hole CB_H2 nor the third hole CB_H3, operation S100 of forming the connection substrate including the first hole, the second hole, and the third hole, operation S300 of forming the base resin layer in the second hole and the third hole of the connection substrate, and operation S400 of curing the base resin layer may be omitted.

In the case where the display device DD includes neither the second hole CB_H2 nor the third hole CB_H3, operation S200 of attaching the connection substrate on the display panel may include attaching the connection substrate CB including the first to third areas R1, R2, and R3 (or R1′, R2′, and R3′) on the display panel DP.

Referring to FIGS. 8 and 9 together, in the case where the display device DD includes neither the second hole CB_H2 nor the third hole CB_H3, the method of fabricating the display device DD may further include forming the cover film CVF on the connection substrate CB. The cover film CVF may cover at least a portion of the connection substrate CB and contact at least a portion of the display panel DP. Because the cover film CVF contacts at least a portion of the display panel DP, the connection substrate CB may be reliably fixed to the display panel DP.

A display device according to an embodiment is applicable to various types of electronic devices. In an embodiment, an electronic device includes the above-described display device and may further include other modules or devices having additional functions in addition to the display device.

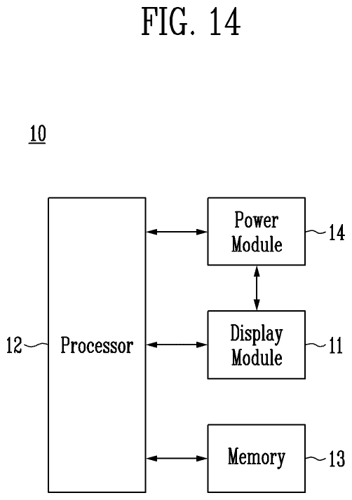

FIG. 14 is a block diagram of an electronic device according to some embodiments. Referring to FIG. 14, the electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data and/or information used to operate the processor 12 or the display module 11. When the processor 12 executes an application stored in the memory 13, image data signals and/or input control signals may be transferred to the display module 11. The display module 11 may process the provided signals and output image information on a display screen.

The power module 14 may include a power supply module, such as a power adapter or a battery device, and a power conversion module. The power conversion module converts power supplied by the power supply module and generates power to operate the electronic device 10.

At least one of the above-described components of the electronic device 10 may be included in the display device according to embodiments as described above. In addition, in terms of functionality, some of the individual modules included in one module may be included in the display device and others may be provided separately from the display device. For example, the display module 11 is included in the display device, whereas the processor 12, the memory 13, and the power module 14 are not included in the display device and are instead provided separately in the electronic device 10.

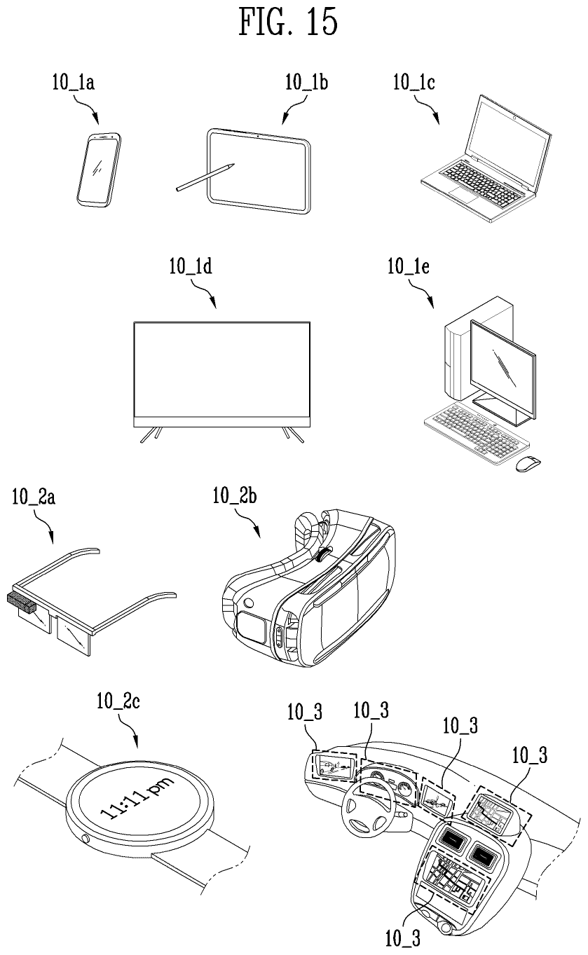

FIG. 15 shows schematic views of various embodiments of an electronic device.

Referring to FIG. 15, various types of electronic devices to which embodiments of a display device are applied may include an electronic device to display images such as a smartphone 10_1a, a tablet PC 10_1b, a laptop computer 10_1c, a television (TV) 10_1d, and a desktop monitor 10_1e, a wearable electronic device including a display module such as smart glasses 10_2a, a head-mounted display (HMD) 10_2b, and a smart watch 10_2c, and an automotive electronic device 10_3 including a display module such as a center information display (CID) disposed at the instrument cluster, the center fascia, and the dashboard of a vehicle, and a room mirror display.

Aspects of some embodiments of the present disclosure may include a display device, an electronic device including the display device and a method of fabricating the display device, which may relatively improve adhesive force between a display panel and a connection substrate, thereby relatively reducing the defect rate.

While aspects of some embodiments have been described above, those skilled in the art will appreciate that various modifications, additions and substitutions are possible, without departing from the scope and spirit of embodiments according to the present disclosure.

Therefore, the embodiments disclosed in this specification are only for illustrative purposes rather than limiting the technical spirit of the present disclosure. The scope of the present disclosure must be defined by the accompanying claims, and their equivalents.

What is claimed is:

1. A display device, comprising:
a display panel including a first area, a second area formed to be bendable from the first area, and a third area extending from the second area;
a driving chip in the third area;
a connection substrate including a first hole overlapping the driving chip and a second hole overlapping the third area, and overlapping at least a portion of the third area; and
a first resin layer in the second hole.

2. The display device according to claim 1, wherein the second hole passes through the connection substrate.

3. The display device according to claim 1, wherein the first resin layer contacts at least a portion of the display panel.

4. The display device according to claim 1, wherein the second hole has a shape of any one of a circle, an ellipse, or a polygon.

5. The display device according to claim 1, wherein the second hole has a circular shape, and
wherein a diameter of the second hole ranges from 30 micrometers (μm) to 1 millimeter (mm).

6. The display device according to claim 1, wherein the second hole has an elliptical shape, and
wherein a semi-minor axis of the second hole ranges from 30 micrometers (μm) to 1 millimeter (mm).

7. The display device according to claim 1,
wherein the second hole has a polygonal shape, and
wherein a shortest diagonal length of the second hole ranges from 30 micrometers (μm) to 1 millimeter (mm).

8. The display device according to claim 1, wherein the first resin layer includes at least one of a thermosetting material or a photo-curable material.

9. The display device according to claim 1,
wherein the connection substrate further includes a third hole overlapping the third area, and
wherein the display device further includes a second resin layer in the third hole.

10. The display device according to claim 9, wherein the third hole passes through the connection substrate, and does not overlap the second hole in a plan view.

11. The display device according to claim 9, wherein each of the second hole and the third hole has a shape of any one of a circle, an ellipse, and a polygon.

12. The display device according to claim 9, wherein each of the first resin layer and the second resin layer includes at least one of a thermosetting material or a photo-curable material.

13. A display device, comprising:
a display panel including a first area, a second area formed to be bendable from the first area, and a third area extending from the second area;
a driving chip in the third area;
a connection substrate including a first hole overlapping the driving chip; and
a cover film on the connection substrate,
wherein the connection substrate includes:
a first substrate area on a first side of the connection substrate;
a second substrate area on a second side of the connection substrate; and
a third substrate area between the first substrate area and the second substrate area,
wherein a length of the connection substrate in a first direction in the third substrate area differs from a length of the connection substrate in the first direction in each of the second substrate area and the first substrate area, and
wherein the cover film contacts at least a portion of the display panel.

14. The display device according to claim 13,
wherein each of the first substrate area and the second substrate area protrudes further in a direction opposite to the first direction than the third substrate area, and
wherein the first direction corresponds to a direction in which the first area and the third area are spaced apart from each other.

15. The display device according to claim 13, wherein the third substrate area protrudes further in a direction opposite to the first direction than each of the first substrate area and the second substrate area.

16. A method of fabricating a display device, comprising:
forming a display panel including a first area, a second area formed to be bendable from the first area, and a third area extending from the second area;
forming a driving chip in the third area;
forming a connection substrate including a first hole and a second hole;
attaching the connection substrate on the display panel;
forming a base resin layer in the second hole; and
curing the base resin layer,
wherein the first hole is formed to overlap the driving chip, and
wherein the second hole is formed to overlap the third area.

17. The method according to claim 16, wherein forming the connection substrate comprises forming the second hole such that the second hole passes through the connection substrate.

18. The method according to claim 16,
wherein forming the base resin layer comprises applying resin into the second hole, and
wherein the resin includes at least one of a thermosetting material or a photo-curable material.

19. The method according to claim 16, wherein curing the base resin layer comprises at least one of photo-curing the base resin layer or thermally curing the base resin layer.

20. The method according to claim 16, wherein forming the connection substrate comprises forming the second hole to have a shape of any one of a circle, an ellipse, and a polygon.

21. An electronic device, comprising:
a display device and a processor,
wherein the display device comprises:
a display panel including a first area, a second area formed to be bendable from the first area, and a third area extending from the second area;
a driving chip in the third area; and
a connection substrate including a first hole overlapping the driving chip.

22. The electronic device according to claim 21, wherein the connection substrate further includes a second hole overlapping the third area, and overlapping at least a portion of the third area, and
wherein the display device further includes a first resin layer in the second hole.

23. The electronic device according to claim 21,
wherein the display device further includes a cover film on the connection substrate,
wherein the connection substrate includes:
a first substrate area on a first side of the connection substrate;
a second substrate area on a second side of the connection substrate; and
a third substrate area between the first substrate area and the second substrate area,
wherein a length of the connection substrate in a first direction in the third substrate area differs from a length of the connection substrate in the first direction in each of the second substrate area and the first substrate area, and
wherein the cover film contacts at least a portion of the display panel.
